(19) United States
(12) Patent Application Publication
(10) Pub. No.: US 2023/0147525 A1
(43) Pub. Date: May 11, 2023

(54) SOLDERING SYSTEM

(71) Applicant: ERSA GmbH, Wertheim (DE)

(72) Inventors: Alexander Diehm, Wertheim (DE); Lothar Endreß, Wertheim (DE); Uwe Hofmann, Würzburg (DE); Benedict Fleischmann, Neubrunn (DE)

(73) Assignee: ERSA GmbH, Wertheim (DE)

(21) Appl. No.: 17/982,621

(22) Filed: Nov. 8, 2022

(30) Foreign Application Priority Data
Nov. 9, 2021 (DE) 10 2021 129 126.7

(51) Int. Cl. B23K 3/08; H05K 3/34

(52) U.S. Cl. CPC B23K 3/085; H05K 3/3494; B23K 2101/42

(57) ABSTRACT

Soldering system, in particular a reflow soldering system, for continuous soldering of printed circuit boards along a transport direction, that includes a process channel having a preheating zone, at least one of a soldering zone and a cooling zone, including a main body, at least one covering hood that is pivotable about a hood axis between a closed position, in which the process channel is closed, and an open position, in which the covering hood is open and the process channel is accessible.

### CROSS REFERENCE TO RELATED APPLICATION

The present application relates and claims priority to German Patent Application No. 10 2021 129 126.7, filed Nov. 9, 2021, the entirety of which is hereby incorporated by reference.

### BACKGROUND

The invention relates to a soldering system, in particular a reflow soldering system, for continuous soldering of printed circuit boards along a transport direction, including a process channel which includes a preheating zone, a soldering zone and/or a cooling zone, including a covering hood and a main body, the covering hood being pivotable about a hood axis provided on the main body between a closed position, in which the process channel is closed, and an open position, in which the covering hood is open and the process channel is accessible. Furthermore, at least one drive unit is provided which includes a motor and a lifting element in such a way that the motor actuates the lifting element for opening and/or closing the covering hood.

By means of reflow soldering systems, so-called SMD components (surface mounted devices) are soldered onto the surface of printed circuit boards by means of solder paste. The solder paste, which is in particular a mixture of solder metal granulate, soldering flux and pasty components, is applied or printed onto the surface of the printed circuit boards for reflow soldering. Subsequently, the components to be soldered are placed in the solder paste. In the reflow soldering process, the soldering item, i.e., the assembly consisting of the printed circuit board, solder paste and components to be soldered, is preheated along the process channel in a preheating zone and, in a soldering zone, is heated to a temperature above the melting point of the solder paste. The solder paste melts and the solder joints are formed in this way. In a cooling zone—if one is present—the soldering item is cooled until the melted solder solidifies before being removed from the reflow soldering system.

Soldering systems for continuous soldering of printed circuit boards are known from DE 10 2019 128 780 A1, DE 10 2019 125 981 A1 and DE 10 2005 055 283 A1.

In the case of reflow soldering systems, the process channel is generally formed by two channel halves, an upper and a lower channel half. The lower channel half is provided in or on the main body and the upper channel half is provided in or on the covering hood. Further components, such as nozzle plates, fan units, air channels conducting the process gas, filter elements and/or cooling elements, are generally provided in or on the process channel or in or on the main body and in or on the covering hood. Overall, a desired temperature profile is thus provided along the transport direction in the process channel, the process gas being blown into the process channel, suctioned out of it, cooled in particular in the cooling zone, cleaned and fed back to the process channel.

The covering hood with the upper channel half, the upper nozzle plates and the further components provided on or in the covering hood can be opened and closed by means of the drive unit mentioned at the outset. In this context, it is known from machines of the applicant having the name Hotflow 3 or Hotflow 4 to secure the motor to the main body and the free end of the lifting element to the covering hood, so that the lifting element displaces the covering hood into the open position when the motor is actuated.

### SUMMARY

The object of the invention is to provide a soldering system in which opening and closing of the covering hood is ensured in a functionally reliable manner without installation space being lost for other components, such as process gas cleaning units, cooling or heating elements, air channels or fan modules. In addition, the components covered by the covering hood should nevertheless be easily accessible.

This object is achieved by means of a transport system. Consequently, it is provided in particular that the motor is arranged on the covering hood and that the lifting element is supported on the main body, in particular with its free end, when the covering hood is displaced into the open position and/or into the closed position.

Because the motor is not arranged on the main body but on the covering hood, no installation space is required for the motor on the main body. Other components provided on the main body, for example process gas cleaning units, cooling or heating elements or fan modules, can consequently be installed without consideration of the drive unit and in particular the motor. Because the motor is provided on the covering hood, the motor is moved together with the covering hood even when the covering hood is opened and closed. The motor must be designed such that it lifts the weight of the covering hood with the upper channel half, with the upper nozzle plates and with the further components provided on or in the covering hood, and can lift its own weight. The wiring of the motor is also to be arranged in such a way that it is laid in or on the covering hood, and that it is also moved together with the covering hood when the covering hood is opened or closed. The invention is based on the idea of taking into account these disadvantages, but providing valuable installation space for other components in the region of the main body.

For support on the main body, the lifting element can provide, in particular, a free end which acts against the main body.

The motor can in particular be provided within the covering hood so that it is not accessible when the covering hood is closed. On the other hand, it is also conceivable to provide the motor outside the covering hood so that it is accessible when the covering hood is closed. The arrangement of the motor outside the covering hood has the advantage that the motor can be better cooled, because the temperatures within the covering hood, in particular in the region of the process zone, are relatively high.

Advantageously, the motor is designed as an electric motor having a drive shaft, the motor then preferably being arranged on the covering hood such that the drive shaft of the drive motor runs parallel to the transport direction. This results in a relatively slim design of the electric motor transversely to the transport direction.

The lifting element actuated by the motor may preferably be designed as a lifting rod or else as a threaded spindle. In particular when the motor is designed as an electric motor having a drive shaft, the lifting element can be designed as a lifting rod with a toothing, the toothing then meshing with a pinion provided on the drive shaft of the electric motor. On the other hand, it is conceivable that the electric motor comprises or drives a threaded spindle, and that the lifting element is designed as a spindle nut which interacts with the threaded spindle, or comprises such a spindle nut. The motor can also be designed as a pneumatic or hydraulic motor, and in particular provide a piston-cylinder unit. The motor is not limited to the aforementioned embodiments, but can include any type of motor that is suitable for being arranged on the covering hood.

Furthermore, it is advantageous if the motor is arranged on the covering hood so as to be pivotable at least to an extent about a first compensation axis running parallel to the hood axis, and if the lifting element is arranged on the main body so as to be pivotable at least to an extent about a second compensation axis likewise running parallel to the hood axis. As a result, a compensating movement of the motor and/or of the lifting element can be compensated for during the opening or closing of the covering hood.

Furthermore, it can be provided that the covering hood encloses a hood chamber, there being provided in the hood chamber the upper channel half having the nozzle plates, heating or cooling elements, air channels conducting process gas and/or fan modules for generating an air flow in the process channel.

In order to form the hood chamber, it is particularly advantageous if the covering hood comprises a frame structure having portal-type frame legs extending transversely to the transport direction, the frame legs each having a first support section directed downward toward the hood axis and a second support section likewise directed downward toward the drive unit, and a central section provided between the support sections, such that the process channel runs below the central sections. The first support sections are preferably provided on the hood axis or are formed by them. The motors of the respective drive unit are then preferably arranged so as to be pivotable to an extent on the second support sections via the respective compensation axis.

Furthermore, it can be provided that a heat shield for heat shielding of the motor is provided in or on the covering hood. The heat shield can be cooled passively or actively by providing suitable cooling elements.

The aforementioned object is also achieved by a soldering system having the features of the preamble of claim 1, which has two long sides and which is characterized in that the hood axis is provided in or in the region of one long side, wherein the covering hood has, on its outer side facing away from the process channel, one or more hood flaps which are arranged so as to be pivotable about a flap axis, running parallel to the hood axis and provided in or in the region of the other long side, between an open position, in which the hood chamber is accessible from above, and a closed position. Such an arrangement has the advantage that the process channel is accessible from the one long side of the soldering system when the covering hood is open. The hood chamber above the upper channel half is accessible from the other long side when the hood flaps are open. In particular if the covering hood is opened during or shortly after the operation of the soldering system, very hot air and possibly also very hot process gas flows out of the hood flap. Due to the fact that the hood flaps are opened from the other long side and the hood chamber is accessible from this other long side, the hood chamber is nevertheless easily accessible even if hot air flows out of the opened covering hood.

The hood flaps, which can in particular be formed as thin sheet metal elements, are relatively light. For this reason, conventional opening elements, for example gas springs, are provided as an opening mechanism for the hood flaps.

An advantageous embodiment results when the flap axis is arranged above the hood axis in the vertical direction.

In this case, the design can also be such that the hood flaps in the closed position come to rest directly, or with the interposition of bearing or damping elements, on the upper side of the frame legs.

Furthermore, it is advantageous if the hood flaps in the closed position each have a horizontal section which is located close to the flap axis and extends in the horizontal direction, and an inclined section which is remote from the flap axis and forms an obtuse angle with the horizontal section. In particular, a handle can be provided on the inclined section, with which the respective hood flap can be opened.

Overall, it is conceivable that the soldering system has at least one covering hood on which two or more hood flaps are provided.

### BRIEF DESCRIPTION OF THE DRAWINGS

Further details of the invention can be found in the following description, which describes and explains an exemplary embodiment of the invention in more detail.

In the drawings:

FIG. 1 shows a reflow soldering system in a side view obliquely from the front with a closed covering hood and closed hood flaps;

FIG. 2 shows the reflow soldering system according to FIG. 1 in a front view with an open covering hood and open hood flaps;

FIG. 3 shows the reflow soldering system according to FIG. 1 obliquely from the front with an open covering hood and open hood flaps;

FIG. 4 shows the reflow soldering system according to FIG. 1 obliquely from the rear with an open covering hood and open hood flaps;

FIG. 5 shows the reflow soldering system according to FIG. 1 obliquely from the front without machine paneling;

FIG. 6 shows an enlarged detail from FIG. 5 with a drive unit; and

FIG. 7 shows the reflow soldering system according to FIG. 1 obliquely from the front with a closed covering hood and open hood flaps.

### DETAILED DESCRIPTION

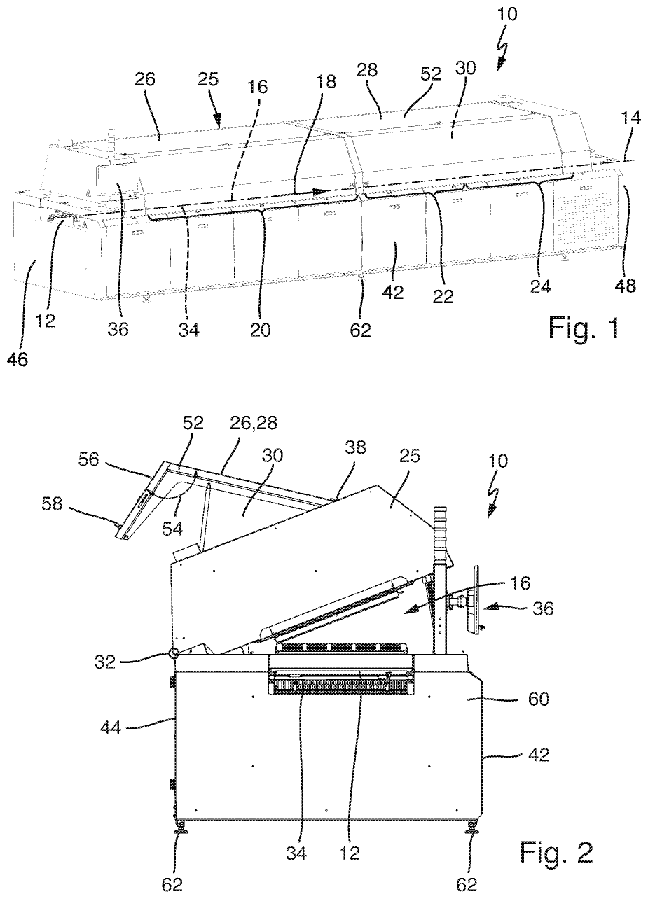

FIG. 1 shows a reflow soldering system 10 for continuous soldering of a soldering item. The reflow soldering system 10 has an inlet 12 and an outlet 14, wherein the material to be soldered reaches the reflow soldering system 10 via the inlet 12 and is discharged from the reflow soldering system 10 via the outlet 14. The material to be soldered is transported along a transport direction 18 through a process channel 16 indicated in FIG. 1.

A preheating zone 20, a soldering zone 22 and a cooling zone 24 are provided in the process channel 16. In the reflow soldering system 10 shown in FIG. 1, a covering hood 25 having two hood flaps 26, 28 is provided for covering the hood chamber 30 enclosed by the covering hood 25, in which chamber an upper channel half of the process channel 16 is located.

As is clear from FIGS. 1 and 2, a communication unit 36 is provided having a screen and an input device by means of which it is possible to communicate with a machine controller of the reflow soldering system 10.

The soldering item, that is to say the printed circuit board provided with the solder paste and fitted with electronic components, is first heated in the preheating zone 20 to a temperature which is below the melting temperature of the solder paste. In the soldering zone 22, the printed circuit board is heated for a certain duration to a process temperature which is above the melting point of the solder paste, so that said solder paste melts in the soldering zone in order to solder the electronic components to the printed circuit board. In the cooling zone 24, the soldering item is cooled so that the liquid solder solidifies before the soldering item is removed at the outlet 14 of the reflow soldering system 10.

A transport system 34 is provided within the reflow soldering system 10 for transporting the circuit boards along the transport direction 18.

As is clear from FIG. 2, the covering hood 25 can be pivoted open about a hood axis 32 extending parallel to the transport direction 18. By pivoting the covering hood 25 open, the interior of the process channel 16 and the transport system 34 are accessible in order to visually check, maintain, clean, set up, replace, and repair them if necessary.

As is further apparent from FIG. 2, the hood flaps 26 can be pivoted open about a flap axis 38 running parallel to the hood axis 32. By pivoting the hood flaps 26, 28 open, the hood chamber 30 above the process channel and thus above the upper channel half is accessible, in which chamber, as is shown below, in particular fan modules, heating elements and air channels are provided. As is also clear from FIG. 2, the flap axis 38 is arranged vertically above the hood axis 32, not only when the covering hood 25 is open, but also when the covering hood 25 is closed.

The soldering system 10 has two long sides 42 and 44 and two short sides 46 and 48. As can be clearly seen in FIG. 2, the hood axis 32 is located in the region of the one rear long side 44. In contrast, the flap axis 38 is located in the region of the front long side 42, or is closer to the front long side 42 than to the rear long side 44.

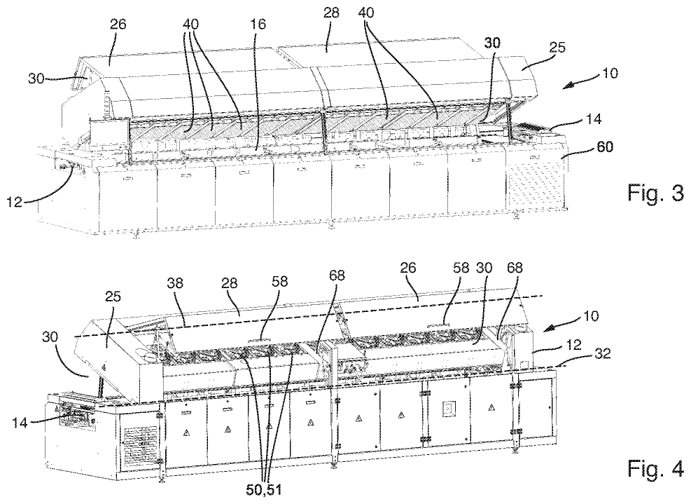

In FIG. 3, in which on the one hand the covering hood 25 and on the other hand the hood flaps 26, 28 are open, the open process channel 16 can be seen in particular. The process channel 16 is formed by two channel halves, an upper channel half and a lower channel half. The lower channel half with the lower nozzle plates 40 is provided in or on a main body 60 and the upper channel half with the upper nozzle plates 40 is provided in or on the covering hood 25. The upper channel half, the upper nozzle plates 40 and further components located in the hood chamber 30 are arranged on the covering hood 25 such that, when the covering hood 25 is opened, they are also pivoted open and the process channel 16 is exposed.

Such an arrangement ensures that, as is clear from FIGS. 2 to 4, the process channel 16 is accessible from the front long side 42 when the covering hood 25 is open, and that the upper hood chamber 30 covered by the hood flaps 26, 28 is accessible from the other rear long side 44.

Among other things, this has the advantage that, when the covering hood 25 is opened, and thus when the process channel 16 is exposed, gas flowing out of the process channel 16 does not flow into the upper hood chamber 30 covered by the cover flaps 26, 28. Furthermore, a plurality of operators can simultaneously check or maintain the process channel 16 and, independently thereof, the hood chamber 30 covered by the cover flaps 26, 28.

As is clear from FIGS. 4, 5 and 7, a plurality of fan modules 50 with fan motors 51, which are provided for generating a provided air flow in the process channel 16, is located above the upper channel half in the upper hood chamber 30 covered by the hood flaps 26, 28. The fan modules 50 can additionally have heating elements in order to provide a predetermined temperature in particular in the preheating zone 20 and the process zone 22. By means of the fan modules 50 or the fan motors 51 thereof, correspondingly heated air is introduced through the nozzle plates 40 into the process channel 16.

If the covering hood 25 is opened, in particular the process channel 16 and the transport system provided therein are therefore accessible. If the hood flaps 26, 28 are folded out, in particular the fan modules 50 provided therein are accessible along with their heating elements as well as air channels provided there.

In their closed position, which is shown in FIG. 1, the two hood flaps 26, 28 have a horizontal section 52 which is located close to the flap axis 38 and extends substantially in the horizontal direction. This horizontal section is adjoined by an inclined section 56 which is remote from the flap axis 38 and forms an obtuse angle 54 with the horizontal section 50. As is clear in particular from FIG. 4, handles 58 for opening the two hood flaps 26, 28 are provided on the inclined section. The obtuse angle 54 can be clearly seen in particular in FIG. 2.

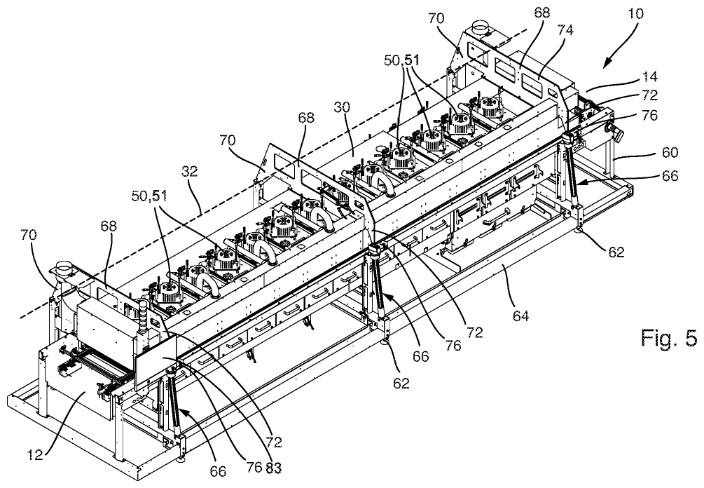

The main body 60 stands on a substrate by means of feet 62. The feet 62 are provided on a lower frame 64. Furthermore, drive units 66 for the motorized opening and closing of the covering hood 25 are provided, and are supported at one end on the lower frame 64 and at the other end on the covering hood 25. As is also clear from FIG. 5, which shows the covering hood 25 without paneling, the covering hood 25 comprises portal-type frame legs 68, each of which has a first support section 70 directed toward the hood axis 32 and a second support section 72 directed toward the respective drive unit 66. A central section 74 is provided in each case between the two support sections.

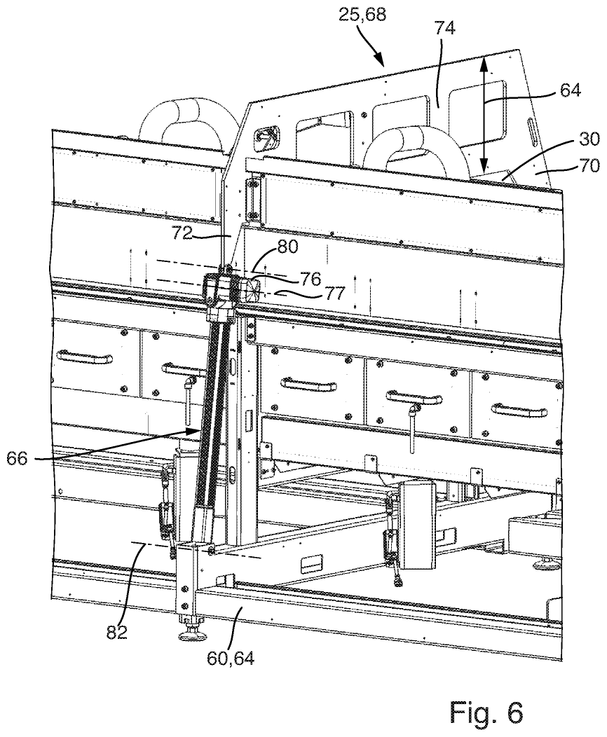

The central frame leg 68 is shown enlarged in FIG. 6. It is clear here that the drive unit 66 in each case comprises a motor 76 and a lifting element 78. The motor 76 is arranged on the covering hood 25 or on the frame leg 68 thereof. The lifting element 78, which can be displaced in the axial direction by the motor 76, engages with its free end on the main body 60 and there on the lower frame 64. By actuating the total of three drive units 66, the covering hood 25 with the upper channel half and the further components can consequently be displaced between its closed position and open position. Because the motors 76 are each arranged on the hood side, they are also moved during opening and closing of the covering hood 25. This arrangement has the advantage that no installation space has to be provided for the motors 76 in the region of the main body 60. The installation space there can be used for other components, such as fan modules, cooling elements, condensate separators or the like provided on the main body 60.

The motors 76 are preferably designed as electric motors and have a drive shaft along the axis 77, which runs parallel to the transport direction 18 and parallel to the hood axis 32 and to the flap axis 38.

The lifting elements 78 of the drive units 66 can in particular be designed as lifting rods or as spindle nuts which interact with a threaded spindle of the respective motor 76, or can comprise such a lifting rod or spindle nut.

In order to compensate for a relative movement between the drive units 66, the main body 64 and the frame legs 68 during movement of the covering hood 25, the respective motor 76 is pivotable on the covering hood 25 or on the support section 72 about a compensation axis 80 running parallel to the hood axis 32. Accordingly, the end of the associated lifting section 74 that faces away from the respective motor 76 is arranged so as to be pivotable to an extent about a compensation axis 82, running parallel to the hood axis 32, on the main body 60.

In order to shield the motors 76 against heat, heat shields 83 are provided in the region of the process zone in the covering hood 25.

As is clear in particular from FIG. 6, the frame legs 68, and in particular their central sections 74, have a vertical extension 84. The arrangement is in this case such that the fan modules 50, as is clear from FIG. 5, are provided in the vertical direction in the region between the upper side and the lower side of the frame legs 68.

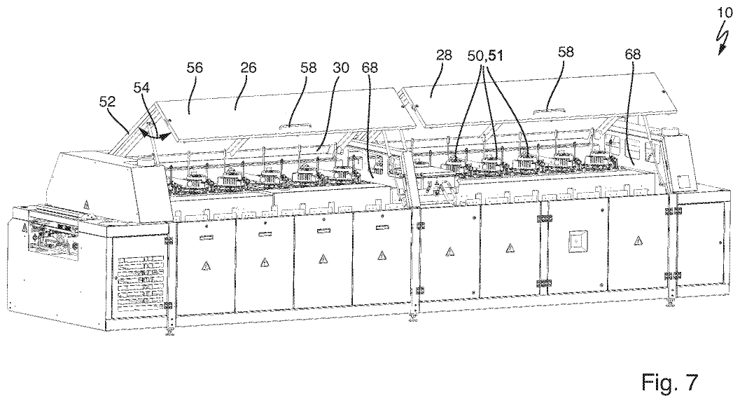

As is clear from FIG. 7, the hood chamber 30 and in particular the fan modules 50 are also easily accessible when the covering hood 25 is closed and only the hood flaps 26, 28 are opened.

What is claimed is:

1. Soldering system for continuous soldering of printed circuit boards along a transport direction,
comprising a process channel which comprises a preheating zone, at least one of a soldering zone and a cooling zone,
comprising a main body and comprising at least one covering hood, the covering hood being pivotable about a hood axis provided parallel to the transport direction, between a closed position, in which the process channel is closed, and an open position, in which the covering hood is open and the process channel is accessible, and
comprising at least one drive unit which comprises a motor and a lifting element such that the motor actuates the lifting element for opening and/or closing the covering hood,
characterized in that the motor is arranged on the covering hood and in that the lifting element is supported on the main body when the covering hood is displaced into the open position and/or into the closed position.

2. Soldering system according to claim 1, characterized in that the motor is designed as an electric motor having a drive shaft and in that the motor is arranged on the covering hood such that the drive shaft runs parallel to the transport direction.

3. Soldering system according to claim 1, characterized in that the lifting element is designed as a lifting rod or as a spindle nut which interacts with a threaded spindle of the motor, or comprises such a lifting rod or spindle nut.

4. Soldering system according to claim 1, characterized in that the motor is arranged on the covering hood so as to be pivotable at least to an extent about a first compensation axis running parallel to the hood axis, and in that the lifting element is arranged on the main body so as to be pivotable at least to an extent about a second compensation axis likewise running parallel to the hood axis.

5. Soldering system according to claim 1, characterized in that the covering hood encloses a hood chamber, there being provided in the hood chamber an upper channel half forming the process channel and having nozzle plates, heating or cooling elements, air channels conducting process gas and/or fan modules for generating a temperature profile and/or an air flow in the process channel.

6. Soldering system according to claim 5, characterized in that, in order to form the hood chamber, the covering hood comprises a frame structure having portal-type frame legs extending transversely to the transport direction, the frame legs each having a first support section directed toward the hood axis and a second support section directed toward the drive unit and a central section provided between the support sections.

7. Soldering system according to claim 5, characterized in that the frame legs each have a vertical extension with an upper side and a lower side, and in that fan modules lie in the vertical direction at least partly in the region between the upper side and the lower side of the frame legs and do not protrude beyond the upper side of the frame legs.

8. Soldering system according to claim 1, characterized in that a heat shield for heat shielding of the motor is provided in or on the covering hood.

9. Soldering system according claim 1, comprising two long sides, characterized in that the hood axis is provided in or in the region of one long side, the covering hood having, on its outer side facing away from the process channel, one or more hood flaps which are arranged so as to be pivotable about a flap axis, running parallel to the hood axis and provided in or in the region of the other long side, between an open position and a closed position.

10. Soldering system according to claim 9, characterized in that the flap axis is arranged above the hood axis in the vertical direction.

11. Soldering system according to claim 9, characterized in that the hood flaps have, in the closed position, a horizontal section which is located close to the flap axis and extends in the horizontal direction and an inclined section which is remote from the flap axis and forms an obtuse angle with the horizontal section.

12. Soldering system according to claim 9, characterized in that the covering hood has two or more hood flaps.
